(19) United States
(12) Patent Application Publication
(10) Pub. No.: US 2018/0203245 A1
(43) Pub. Date: Jul. 19, 2018

(54) 3D MICRO LED DISPLAY DEVICE

(71) Applicant: SHENZHEN CHINA STAR OPTOELECTRONICS TECHNOLOGY CO., Guangdong (CN)

(72) Inventor: Lixuan Chen, Shenzhen City (CN)

(21) Appl. No.: 15/116,219

(22) PCT Filed: Jul. 15, 2016
(86) PCT No.: PCT/CN2016/090119

§ 371 Date: Aug. 3, 2016

(30) Foreign Application Priority Data
Jun. 22, 2016 (CN) 201610460334.6

(51) Int. Cl. G02B 27/26; H01L 25/075; G02B 5/30

(52) U.S. Cl. CPC G02B 27/26; H01L 25/0753; H01L 33/0079; G02B 5/3083; G02B 5/3058

(57) ABSTRACT

The invention provides a 3D micro LED display device, by disposing a stack structure of a one-dimensional metal grating structure and a two-dimensional metal grating structure on the micro LED display panel, using the one-dimensional metal grating structure to achieve polarizing the light emitted by the micro LED display panel to produce linear polarization light, using the two-dimensional metal grating structure to achieve the function of ¼ wave plate to process the linear polarization light produced by the one-dimensional metal grating structure to produce right circularly polarized light and left circularly polarized light to achieve 3D display, to fully utilize the high-resolution, high-luminance and small-size advantages of the micro LED display panel to realize high-quality 3D display.

### BACKGROUND OF THE INVENTION

### 1. Field of the Invention

The present invention relates to the field of display, and in particular to a three-dimensional (3D) micro light-emitting diode (micro LED) display device.

### 2. The Related Arts

The panel display device, due to the advantages of high display quality, low power-consumption, thin size and wide application, is widely used in mobile phones, TV, PDA, digital camera, notebook PC, desktop PC, and so on, and becomes the mainstream technology.

The micro light-emitting diode (micro LED, μLED) display device is a display device which utilizes high density micro-scaled LED array integrated on a substrate as display pixels to achieve image display. Similar to a larger-scaled outdoor LED display, each pixel is addressable and individually driven to emit light, and can be viewed as a reduce-sized outdoor LED display by reducing the inter-pixel distance from cm scale to mm scale. Micro LED display device and the organic light-emitting diode (OLED) are both self-luminous, but the micro LED shows the advantages of higher material stability, longer lifespan and no image imprinting as compared to the OLED, and is considered as the major competing technology for OLED display device.

The micro transfer printing (MTP) is the mainstream technology to manufacture micro LED display device. Specifically, first, the micro LED element is grown on the sapphire-based substrate; a laser lift-off (LLO) technology is used to separate the micro LED bare chip from the sapphire-based substrate, and then a patterned polydimethylsiloxane (PDMS) transfer stamp is used to adsorb to the micro LED bare chip off from the sapphire-based substrate; the PDMS transfer stamp is aligned with the receiving substrate for positioning; and then the micro LED bare chip adsorbed by the PDMS transfer stamp is attached to the pre-set position on the receiving substrate; and then the PDMS transfer stamp is peeled off to accomplish micro LED bare chip transfer to further manufacture the micro LED display device.

One-dimensional metal grating is cyclic structure arranged in the metal and dielectric layers, comprising a plurality of metal bars arranged in parallel, with spacing formed between the respective metal bars, having a birefringence effect, having a high extinction ratio on the light filed of the transverse magnetic field (TM) and the transverse electric field (TE) state, and able to transmit the TM light perpendicular to metal bar arrangement direction and reflect the TE light parallel to the metal bar arrangement direction to act as a polarizer. Unlike one-dimensional metal grating, the known technology also provides a two-dimensional metal grating, comprising: a plurality of rectangular blocks arranged in an array, with spacing formed between adjacent rows and adjacent columns. The two-dimensional metal gratings can not only serve the polarization function, but also can be used to build ¼ wave plate (quarter-wave plate) with the birefringence effect. In addition, the fast and slow axes of the built ¼ wave plate can be changed with the change in gating design.

### SUMMARY OF THE INVENTION

The object of the present invention is to provide a 3D micro LEDs display device, able to achieve 3D display and improve display quality of 3D micro LED display device.

To achieve the above object, the present invention provides a 3D micro LED display device, which comprises: a substrate, a plurality of micro LEDs disposed on the substrate and arranged in an array, a polarizing layer disposed on the plurality of micro LEDs, and a ¼ wave plate layer disposed on the polarizing layer; the polarizing layer being a one-dimensional metal grating structure, and the ¼ wave plate layer being a two-dimensional metal grating structure; the ¼ wave plate layer comprising a plurality of ¼ wave plate areas arranged sequentially, and the fast axes of two adjacent ¼ wave plate areas being mutually perpendicular; the polarization direction of the polarizing layer forming a 45 degree angle with the fast axis of each ¼ wave plate area.

Each ¼ wave plate area corresponds to a row of micro LEDs.

Each ¼ wave plate area corresponds to a column of micro LEDs.

Each ¼ wave plate area corresponds to a micro LED.

The two-dimensional metal grating structure has a height of 50-300 nm.

The cycles of the two-dimensional metal grating structure in both dimensions are both 40-300 nm.

The plurality of micro LEDs comprises: red micro LEDs, green micro LEDs and blue micro LEDs.

The plurality of micro LEDs is manufactured by micro transfer printing (MTP).

The 3D micro LED display device is a helmet-type virtual reality display device or a glasses-type virtual reality display device.

The present invention also provides a 3D micro LED display device, which comprises: a substrate, a plurality of micro LEDs disposed on the substrate and arranged in an array, a polarizing layer disposed on the plurality of micro LEDs, and a ¼ wave plate layer disposed on the polarizing layer; the polarizing layer being a one-dimensional metal grating structure, and the ¼ wave plate layer being a two-dimensional metal grating structure; the ¼ wave plate layer comprising a plurality of ¼ wave plate areas arranged sequentially, and the fast axes of two adjacent ¼ wave plate areas being mutually perpendicular; the polarization direction of the polarizing layer forming a 45 degree angle with the fast axis of each ¼ wave plate area; wherein the plurality of micro LEDs comprising: red micro LEDs, green micro LEDs and blue micro LEDs; wherein the plurality of micro LEDs being manufactured by micro transfer printing (MTP); and wherein the 3D micro LED display device being a helmet-type virtual reality display device or a glasses-type virtual reality display device.

Compared to the known techniques, the present invention provides the following advantages: the present invention provides a 3D micro LED display device, by disposing a stack structure of a one-dimensional metal grating structure and a two-dimensional metal grating structure on the micro LED display panel, using the one-dimensional metal grating structure to achieve polarizing the light emitted by the micro LED display panel to produce linear polarization light, using the two-dimensional metal grating structure to achieve the function of ¼ wave plate to process the linear polarization light produced by the one-dimensional metal grating structure to produce right circularly polarized light and left circularly polarized light to achieve 3D display, to fully utilize the high-resolution, high-luminance and small-size advantages of the micro LED display panel to realize high-quality 3D display.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a cross-sectional view showing the structure of 3D micro LED display device provided by an embodiment of the present invention;

FIG. 2 is a top view showing the 3D micro LED display device provided by a first embodiment of the present invention;

FIG. 3 is a top view showing the 3D micro LED display device provided by a second embodiment of the present invention; and

FIG. 4 is a top view showing the 3D micro LED display device provided by a third embodiment of the present invention.

### DETAILED DESCRIPTION OF THE PREFERRED EMBODIMENTS

To further explain the technical means and effect of the present invention, the following refers to embodiments and drawings for detailed description.

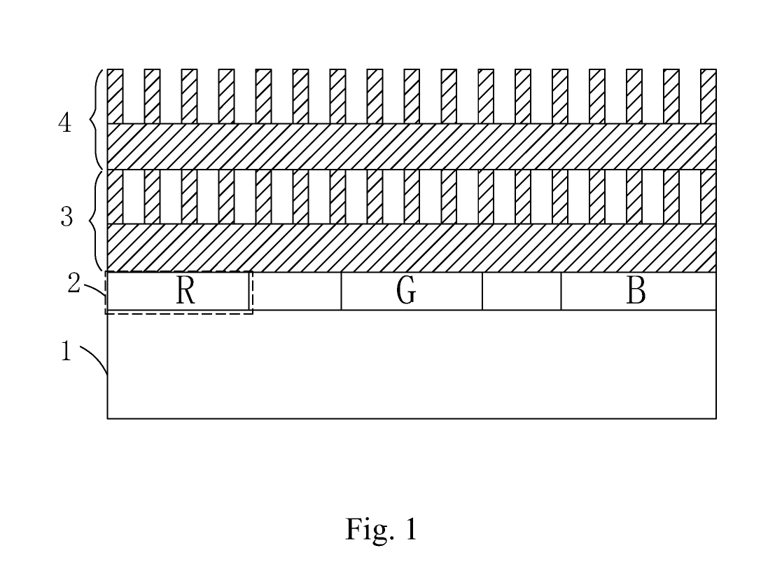

Refer to FIG. 1. The present invention provides the present invention provides a 3D micro LED display device, which comprises: a substrate 1, a plurality of micro LEDs 2 disposed on the substrate 1 and arranged in an array, a polarizing layer 3 disposed on the plurality of micro LEDs 2, and a ¼ wave plate layer 4 disposed on the polarizing layer 3.

Specifically, the substrate 1 and the plurality of micro LEDs 2 disposed on the substrate 1 together form a micro LED display panel. The polarizing layer 3 is a one-dimensional metal grating structure, and the ¼ wave plate layer 4 is a two-dimensional metal grating structure.

Moreover, by designing the two-dimensional structure of the ¼ wave plate layer 4, the ¼ wave plate layer comprises a plurality of ¼ wave plate areas 41 arranged sequentially, and the fast axes of two adjacent ¼ wave plate areas 41 are mutually perpendicular.

It should be noted that the polarization direction of the polarizing layer 3 forms a 45 degree angle with the fast axis of each ¼ wave plate area 41. The light emitted by the micro LEDs 2, after passing through the polarizing layer 3, produces a linear polarization light, whose light vector forms a 45 degree angle with the fast axis of each ¼ wave plate area 41. After the linear polarization light passing through two ¼ wave plate areas 41 with fast axes mutually perpendicular, a right circularly polarized light and a left circularly polarized light are produced.

At this point, the viewer wearing a pair of polarization 3D glasses can see 3D images. It should be noted that the, by disposing polarizers with left and right polarization mutually perpendicular at the emitting side of the 3D micro LED display device (similar to the polarization 3D glasses), the viewer can also see different images with left eye and right eye to achieve naked-eye 3D display.

Specifically, the size and arrangement of each ¼ wave plate area 41 of the ¼ wave plate layer 4 can vary depending on the application.

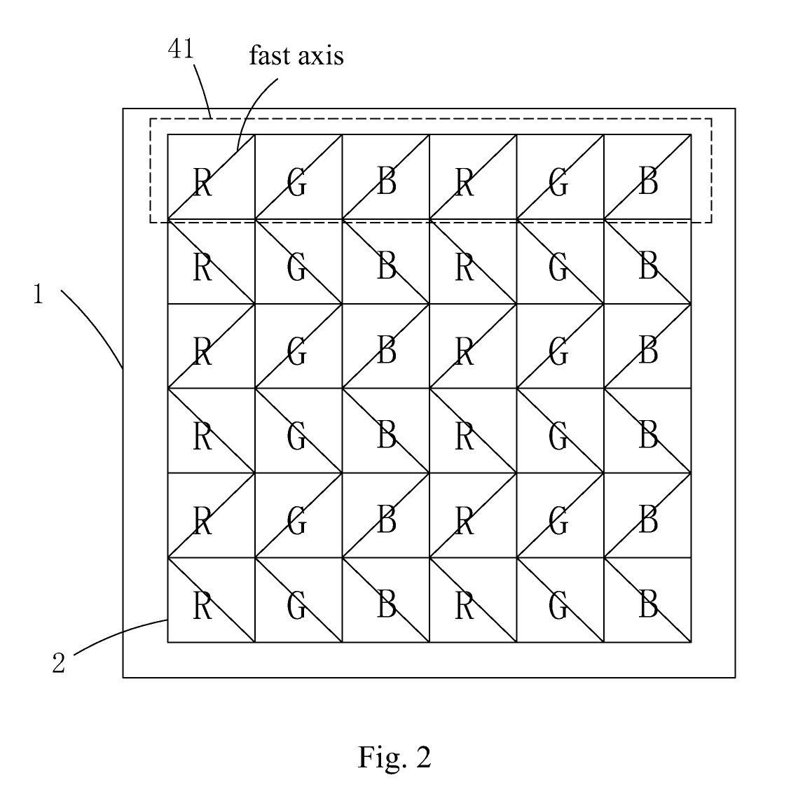

Refer to FIG. 2. In the first embodiment of the present invention, each ¼ wave plate area corresponds to a row of micro LEDs 2. That is, the micro LEDs 2 of the same row correspond to the same fast axis of the ¼ wave plate layer 4, and the micro LEDs 2 of two adjacent rows correspond to the ¼ wave plate layer 4 with mutually perpendicular fast axes so that the micro LEDs 2 of two adjacent rows produce a right circularly polarized light and a left circularly polarized light to achieve 3D display.

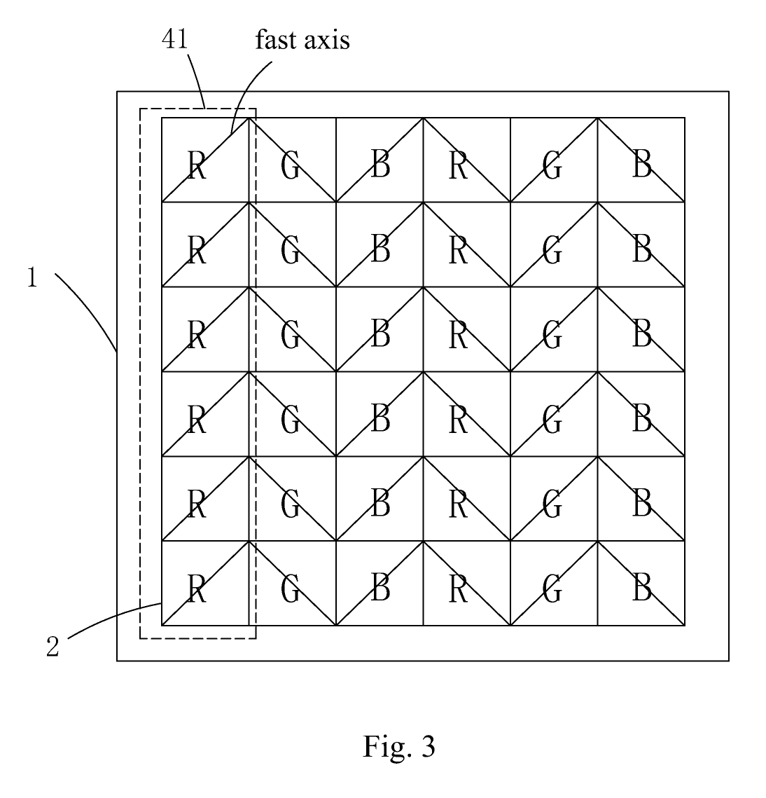

Refer to FIG. 3. In the second embodiment of the present invention, each ¼ wave plate area corresponds to a column of micro LEDs 2. That is, the micro LEDs 2 of the same column correspond to the same fast axis of the ¼ wave plate layer 4, and the micro LEDs 2 of two adjacent columns correspond to the ¼ wave plate layer 4 with mutually perpendicular fast axes so that the micro LEDs 2 of two adjacent columns produce a right circularly polarized light and a left circularly polarized light to achieve 3D display.

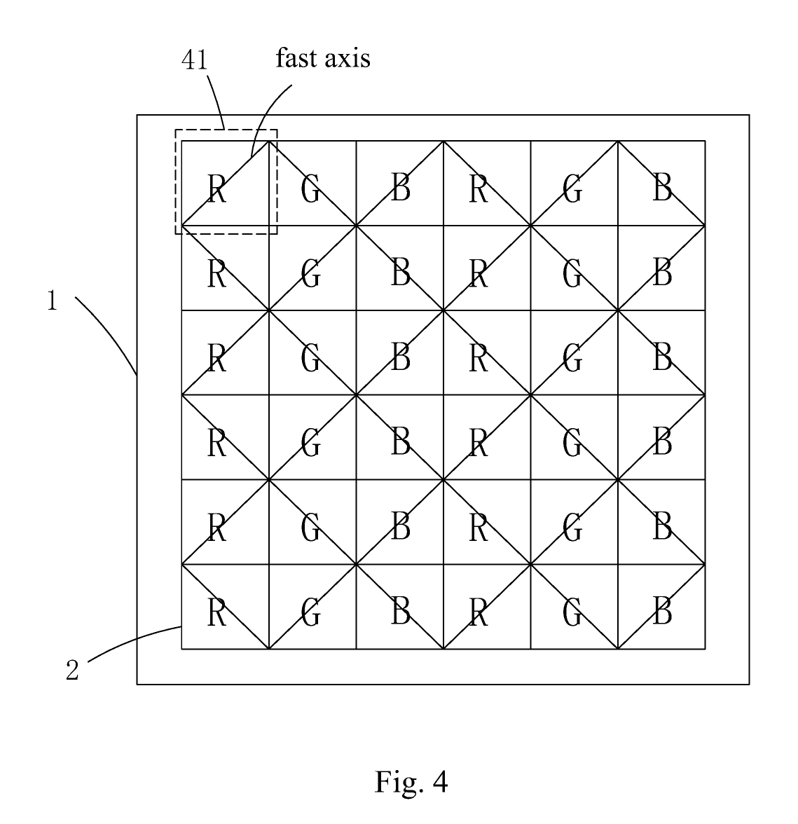

Refer to FIG. 4. In the third embodiment of the present invention, each ¼ wave plate area corresponds to a micro LED 2. That is, the same micro LED 2 corresponds to the same fast axis of the ¼ wave plate layer 4, and two adjacent micro LEDs 2 correspond to the ¼ wave plate layer 4 with mutually perpendicular fast axes so that the two adjacent micro LEDs 2 produce a right circularly polarized light and a left circularly polarized light to achieve 3D display.

Optionally, the two-dimensional metal grating structure has a height of 50-300 nm, and the cycles of the two-dimensional metal grating structure in both dimensions are both 40-300 nm.

Preferably, the plurality of micro LEDs 2 comprises: red micro LEDs R, green micro LEDs G and blue micro LEDs B, and uses RGB to achieve color display.

Specifically, the plurality of micro LEDs is manufactured by micro transfer printing (MTP). Specifically, the process comprises: providing a native substrate, growing a plurality of micro LEDs 2 on a native substrate, using an MTP transfer stamp to transfer the plurality of micro LEDs 2 to the substrate 1.

It should be noted that the 3D micro LED display device is a helmet-type virtual reality display device or a glasses-type virtual reality display device.

In summary, the present invention provides a 3D micro LED display device, by disposing a stack structure of a one-dimensional metal grating structure and a two-dimensional metal grating structure on the micro LED display panel, using the one-dimensional metal grating structure to achieve polarizing the light emitted by the micro LED display panel to produce linear polarization light, using the two-dimensional metal grating structure to achieve the function of ¼ wave plate to process the linear polarization light produced by the one-dimensional metal grating structure to produce right circularly polarized light and left circularly polarized light to achieve 3D display, to fully utilize the high-resolution, high-luminance and small-size advantages of the micro LED display panel to realize high-quality 3D display.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A three-dimensional (3D) micro light-emitting diode (LED) display device, which comprises: a substrate, a plurality of micro LEDs disposed on the substrate and arranged in an array, a polarizing layer disposed on the plurality of micro LEDs, and a ¼ wave plate layer disposed on the polarizing layer;
the polarizing layer being a one-dimensional metal grating structure, and the ¼ wave plate layer being a two-dimensional metal grating structure;
the ¼ wave plate layer comprising a plurality of ¼ wave plate areas arranged sequentially, and the fast axes of two adjacent ¼ wave plate areas being mutually perpendicular; and
the polarization direction of the polarizing layer forming a 45 degree angle with the fast axis of each ¼ wave plate area.

2. The 3D micro LED display device as claimed in claim 1, wherein each ¼ wave plate area corresponds to a row of micro LEDs.

3. The 3D micro LED display device as claimed in claim 1, wherein each ¼ wave plate area corresponds to a column of micro LEDs.

4. The 3D micro LED display device as claimed in claim 1, wherein each ¼ wave plate area corresponds to a micro LED.

5. The 3D micro LED display device as claimed in claim 1, wherein the two-dimensional metal grating structure has a height of 50-300 nm.

6. The 3D micro LED display device as claimed in claim 1, wherein the cycles of the two-dimensional metal grating structure in both dimensions are both 40-300 nm.

7. The 3D micro LED display device as claimed in claim 1, wherein the plurality of micro LEDs comprises: red micro LEDs, green micro LEDs and blue micro LEDs.

8. The 3D micro LED display device as claimed in claim 1, wherein the plurality of micro LEDs is manufactured by micro transfer printing (MTP).

9. The 3D micro LED display device as claimed in claim 1, wherein the 3D micro LED display device is a helmet-type virtual reality display device or a glasses-type virtual reality display device.

10. A three-dimensional (3D) micro light-emitting diode (LED) display device, which comprises: a substrate, a plurality of micro LEDs disposed on the substrate and arranged in an array, a polarizing layer disposed on the plurality of micro LEDs, and a ¼ wave plate layer disposed on the polarizing layer;
the polarizing layer being a one-dimensional metal grating structure, and the ¼ wave plate layer being a two-dimensional metal grating structure;
the ¼ wave plate layer comprising a plurality of ¼ wave plate areas arranged sequentially, and the fast axes of two adjacent ¼ wave plate areas being mutually perpendicular; and
the polarization direction of the polarizing layer forming a 45 degree angle with the fast axis of each ¼ wave plate area;
wherein the plurality of micro LEDs comprising: red micro LEDs, green micro LEDs and blue micro LEDs.
wherein the plurality of micro LEDs being manufactured by micro transfer printing (MTP); and
wherein the 3D micro LED display device being a helmet-type virtual reality display device or a glasses-type virtual reality display device.

11. The 3D micro LED display device as claimed in claim 10, wherein each ¼ wave plate area corresponds to a row of micro LEDs.

12. The 3D micro LED display device as claimed in claim 10, wherein each ¼ wave plate area corresponds to a column of micro LEDs.

13. The 3D micro LED display device as claimed in claim 10, wherein each ¼ wave plate area corresponds to a micro LED.

14. The 3D micro LED display device as claimed in claim 10, wherein the two-dimensional metal grating structure has a height of 50-300 nm.

15. The 3D micro LED display device as claimed in claim 10, wherein the cycles of the two-dimensional metal grating structure in both dimensions are both 40-300 nm.
